(19) United States
(12) Patent Application Publication
(10) Pub. No.: US 2012/0129305 A1
(43) Pub. Date: May 24, 2012

(54) METHOD FOR MANUFACTURING A MOS-FIELD EFFECT TRANSISTOR

(76) Inventors: Rohan S. Braithwaite, Gilbert, AZ (US); Gregory Dix, Tempe, AZ (US); Harold Kline, Phoenix, AZ (US)

(21) Appl. No.: 13/288,148

(22) Filed: Nov. 3, 2011

Related U.S. Application Data
(60) Provisional application No. 61/415,464, filed on Nov. 19, 2010.

(51) Int. Cl. H01L 21/336

(52) U.S. Cl. 438/268; 438/302; 438/286; 257/E21.41; 257/E21.409; 257/E21.437

(57) ABSTRACT

A method for manufacturing a Metal-Oxide-Semiconductor Field-Effect-Transistor (MOSFET) has the step of implanting a base region of said MOSFET within an epitaxial layer of a semiconductor chip comprising an insulated gate structure used as a masking element, wherein the implant beam is angled with respect to a vertical axis of the semiconductor chip such that the base region extends sufficiently under the gate to form a Power-MOSFET.

### CROSS-REFERENCE TO RELATED APPLICATIONS

This application claims the benefit of U.S. Provisional Application No. 61/415,464 filed on Nov. 19, 2010, entitled “USING AN ANGLED IMPLANT TO FORM A P-BASE REGION”, which is incorporated herein in its entirety.

### TECHNICAL FIELD

This application concerns a method for manufacturing a MOS-Field Effect Transistor (FET).

### BACKGROUND

Power metal oxide semiconductor field-effect transistors (MOSFET) are generally used to handle high power levels in comparison to small signal transistors in integrated circuits. Such power transistors can be formed laterally or vertically within a semiconductor chip.

As shown in FIG. 7, to manufacture a vertical transistor device, an N⁻ epitaxial layer is formed on a generally heavily doped N⁺ substrate 715. In a vertical transistor as shown in FIG. 7, from the top into the epitaxial layer 710 there are formed N⁺ doped left and right source regions 730 surrounded by P-doped region 720 which forms the P-bases. Before formation of the P-base 720, a polysilicon gate 740 is formed on an insulating layer 750 such as SIO₂. The gate 740 is then used as a mask to implant the source and P-base regions. The P-base regions 720 form the channel length of the device. In order to get sufficient dopant underneath the polysilicon gate 740, a heavy implant drive shown with arrows 770 is needed. A similar process is used for lateral transistor devices. The drive causes the dopant to move both vertically, and horizontally. A key function of the drive is the horizontal diffusion under the gate.

However, if such a power transistor is to be integrated into a semiconductor module having a variety of integrated circuit structures and therefore into an existing process flow, such an integration brings many challenges with it. For example, the above mentioned heavy drive of the implanted P-base regions has an impact on the overall thermal budget in a manufacturing process. These budgets are often at their limit and do not allow for additional thermal energy without having an impact on the functionality of the integrated components. Thus, changing an existing thermal budget is often not an available option. Therefore a need exists for a manufacturing process that allows to combine power transistors with existing integrated structures in a manufacturing process without changing the thermal budget or without exceeding the thermal budget.

### SUMMARY

According to an embodiment, a method for manufacturing a Metal-Oxide-Semiconductor Field-Effect-Transistor (MOSFET) may comprise the step of implanting a base region of said MOSFET within an epitaxial layer of a semiconductor chip comprising an insulated gate structure used as a masking element, wherein the implant beam is angled with respect to a vertical axis of the semiconductor chip such that the base region extends sufficiently under the gate to form a Power-MOSFET.

According to a further embodiment, the implant beam can be angled with respect to a vertical axis of the semiconductor chip with an angle greater than 10 degrees and less than 50 degrees. According to a further embodiment, the MOSFET can be formed within a single manufacturing process for forming a plurality of integrated devices and said MOSFET in the semiconductor chip. According to a further embodiment, the plurality of devices may form a microcontroller controlling said MOSFET. According to a further embodiment, the plurality of devices may form a pulse width modulator controlling said MOSFET. According to a further embodiment, at least two MOSFETs can be formed during said manufacturing process and a drain of a first MOSFET is connected to a source of a second MOSFET. According to a further embodiment, a plurality of MOSFETs can be formed during said manufacturing process and said plurality of MOSFETs are interconnected to form an H-bridge. According to a further embodiment, the semiconductor chip can be rotated around the vertical axis during the step of implanting. According to a further embodiment, the angled implant source can be rotated during the step of implanting. According to a further embodiment, the base region can be formed on one side of the gate and further comprising forming a source region within the base region implanted by the implanting step. According to a further embodiment, the base MOSFET can be formed within an area defined by surrounding field oxide. According to a further embodiment, the method may further comprise the step of forming a buried layer prior to the implanting step. According to a further embodiment, the substrate can be an N+ substrate. According to a further embodiment, the substrate can be a P-type substrate and the buried layer is an N+ buried layer. According to a further embodiment, the epitaxial layer can be a low doped P-type silicon layer comprising selective N-doped regions. According to a further embodiment, the method may further comprise forming a drain region on the other side of the gate extending from a top surface into the epitaxial layer. According to a further embodiment, the method may further comprise forming a plurality of transistor cells within said epitaxial layer and forming metal layers to interconnect said gates, drain and source regions of said plurality of transistor cells. According to a further embodiment, right and left base regions can be formed with respect to the gate by rotating the semiconductor chip around the vertical axis during the step of implanting and further comprising the step of forming right and left source regions within the right and left base regions, respectively. According to a further embodiment, the method may further comprise forming a drain region on a backside of said semiconductor chip. According to a further embodiment, the method may further comprise forming a lightly doped drain zone between said left and right base regions. According to a further embodiment, the method may further comprise forming a plurality of transistor cells within said epitaxial layer and forming metal layers to interconnect said gates and source regions of said plurality of transistor cells.

### BRIEF DESCRIPTION OF THE DRAWINGS

FIG. 1 shows an embodiment a lateral power MOS-FET manufactured according to an embodiment;

FIG. 2 shows an embodiment a vertical power MOS-FET manufactured according to another embodiment;

FIGS. 3A-3C shows certain manufacturing steps for the embodiment shown in FIG. 1;

FIGS. 4A-4B shows certain manufacturing steps for the embodiment shown in FIG. 2;

FIG. 5 shows a cross section of a power transistor manufactured according to various embodiments;

FIGS. 6A-6B shows schematically the integration of two power transistors manufactured according to various embodiments in combination with a microcontroller; and

FIG. 7 shows a conventional method for forming a power transistor in a semiconductor layer.

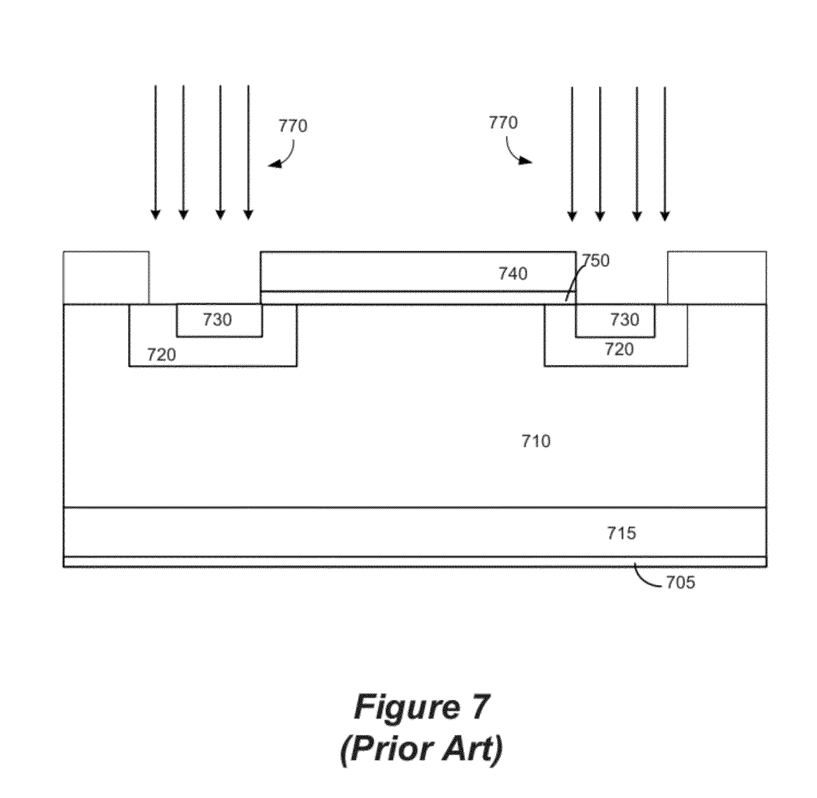

### DETAILED DESCRIPTION

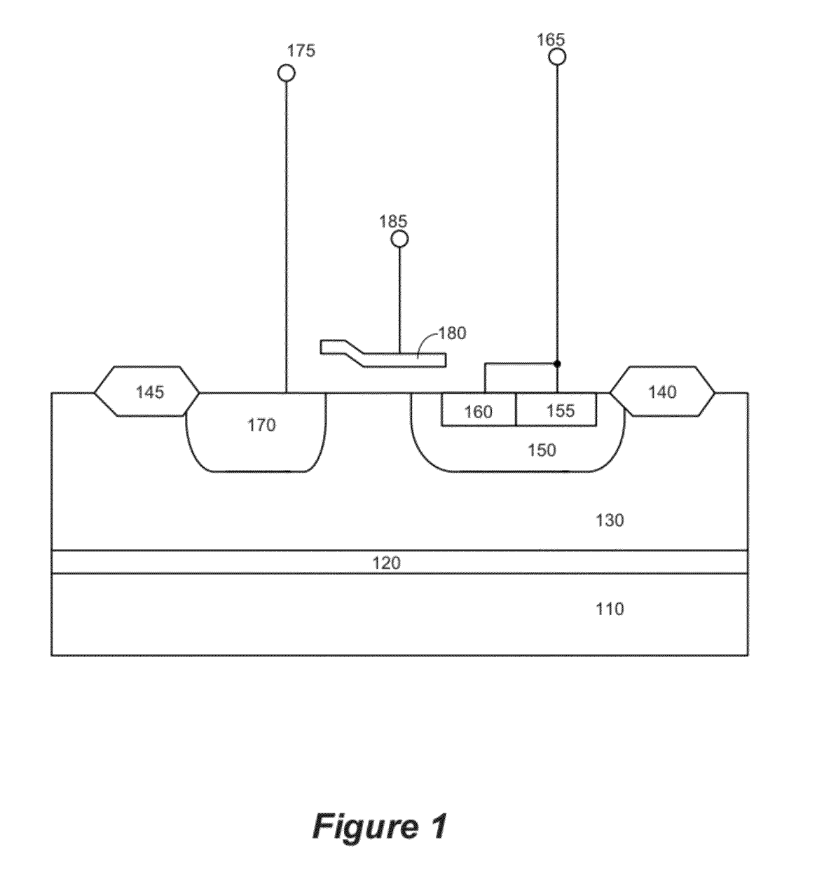

FIG. 1 shows a cross-sectional view of a lateral Power-MOS-FET which can be manufactured according to various embodiments. According to an embodiment, a P-type substrate 110 may have a buried N+ layer 120 on top of which a low doped (45 Ohm/cm) P-type silicon layer forms the epitaxial layer. Such a structure may further have N-doped selective regions 130 within the epitaxial layer which may provide for a better control for the device formation and consistency.

However, according to other embodiments, an N+ doped substrate 110 is provided on top of which an N− epitaxial layer 130 is formed for creating high voltage power transistors. Between the epitaxial layer 130 and the substrate 110 there can be an N doped buried layer (NBL) 120 similar as in the above mentioned embodiment used for forming a well or insulating the transistor from other devices formed within the epitaxial layer 130. Other substrate-epitaxial layer structures may be used, in particular with or without buried layers.

For separation of the transistor from other structures there may also be formed a left and right field oxide 140, 145 according to other embodiments.

Within the active area, for example, the area defined by the left and right field oxide 140, 145, from the top into the epitaxial layer 130 on the right side as shown in FIG. 1, there extends a P-doped base region 150 within which a source region 160 is formed. The P-base 150 is connected with the source region 160 through a contact zone 155 and an interconnecting metal layer 165. A drain region 170 is formed on the left side adjoining the field oxide 145. An area between the drain and source regions 170, 160 which will form a channel is covered by an insulated polysilicon gate 180. Gate 180 and drain 170 are connected with respective metal layers 185 and 175, respectively. With appropriate voltage applied to the source, drain and gate, the channel can be formed within the P-base 150 between the source region and the epitaxial layer 130 allowing for current to flow from the source to the drain. To this end, the P-base must extend far enough under the polysilicon gate 180. According to various embodiments, this P-base region can be formed by an angled implant along with “standard” existing thermal diffusion steps yielding an equivalent P-Base region of a much higher thermal budget process without changing the thermal budget as will be explained in more detail below.

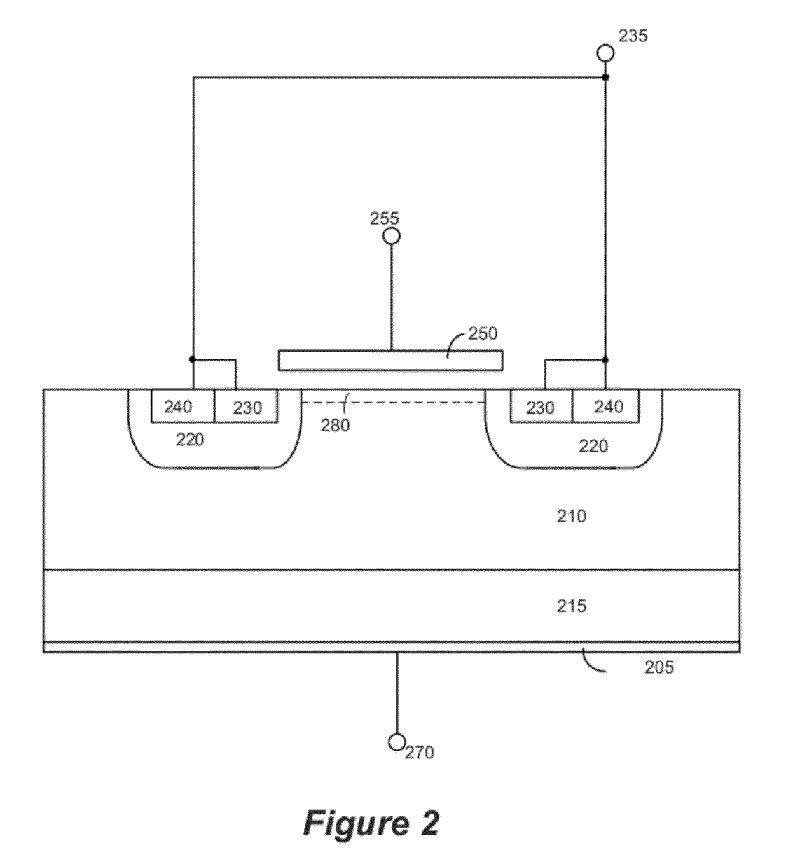

FIG. 2 shows a cross-sectional view of a vertical Power-MOS-FET which can be manufactured according to various embodiments. Again, an N+ doped substrate 215 is provided on top of which an N− epitaxial layer 210 is formed for creating high voltage power transistors. As mentioned above, other substrate-epitaxial layer structures may be used. From the top into the epitaxial layer 210 there are formed N+ doped left and right source regions 230 each surrounded by a P-doped region 220 which forms the P-base of the transistor. Each P-base 220 can furthermore be surrounded by an associated out diffusion area (not shown). A source contact metal layer 235 generally contacts both regions 230 and 220 on the surface of the die through a contact area 240 within the P-base 220. The metal layer 235 is also used to connect both left and right source region 230. An insulating layer insulates a gate 250 from the underlying epitaxial layer and covers the area between the left and right sources and thus a part of the respective P-base region 120 which forms respective channels when the appropriate voltages are applied to the gate 250. The bottom side of this vertical transistor has again another metal layer 205 forming for connection to a drain contact 270. The P-base regions 220 are again formed by an angled implant as will be disclosed in more detail below.

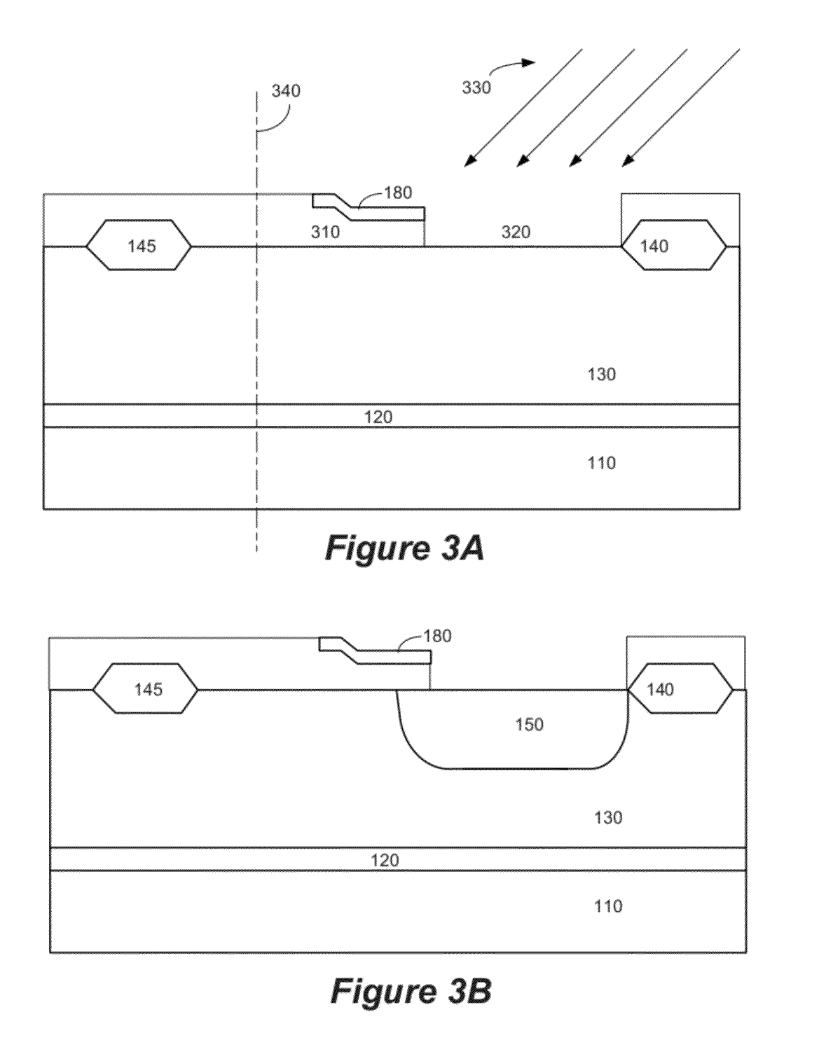

FIG. 3A-3C show exemplary process steps for manufacturing a device as shown in FIG. 1. As shown in FIG. 3A, on a P-doped substrate 110 an N+ buried layer 120 has been implanted and an epitaxial layer 130 has been grown and doped N−. On top of the epitaxial layer 130 an oxide layer 310 is deposited. Field oxides 140 and 145 are formed using respective masking techniques. Then a gate layer is deposited using for example polysilicon. The gate layer is then patterned using masking and etching techniques well known in the art to form gate 180. Again, this structure is covered by a photo mask and an opening 320 is formed for implanting the base region of the transistor.

To implant the P-base region, instead of a conventional vertical implant beam, an implant beam 330 is used to form the P-base region wherein the implant beam 330 is angled with respect to a vertical axis 340 of the semiconductor chip. Such an angled beam may have an energy level of for example, 50 KeV. This energy level can be used, for example, for an N-DMOS device with a voltage point <42V. Hence, depending on the device design other energy levels may apply. The angle may, for example, preferably be 45° and directed towards the gate as shown in FIG. 3A. The energy and angle can change if the operation voltage is different. Also, the type of transistor which dictates the species will also cause the energy and/or angle to change. For example, according to another embodiment, a P-DMOS may use a 120 KeV implant at 35°. Thus, there can be many variations. According to various embodiments, the implant angle can be greater than 10° and less than 50°. As for the energies, according to various embodiment, these levels can vary greatly.

The energy level used is equivalent of energy levels used within an existing process flow and can therefore substitute a corresponding step in the process. Thus, existing thermal cycles activate and drive the dopant concentration to the right spot to handle the voltage and provide the best Rdson possible for each device. Thus, the thermal budget for manufacturing the entire device will not be exceeded. FIG. 3B shows the P-base region 150 after an associated diffusion step has been performed. As can be seen the angled implant beam causes the P-base region 150 to extent sufficiently under the gate 180 so that a channel can be formed when an appropriate voltage is applied to the gate 180. FIG. 3C shows the device after the source region 160 and the P-base contact region 155 have been formed within the P-base region 120 and drain region 170 has been formed within the epitaxial layer 130. Metal layers can then be used to connect the source/P-base, gate and drain with respective contacts.

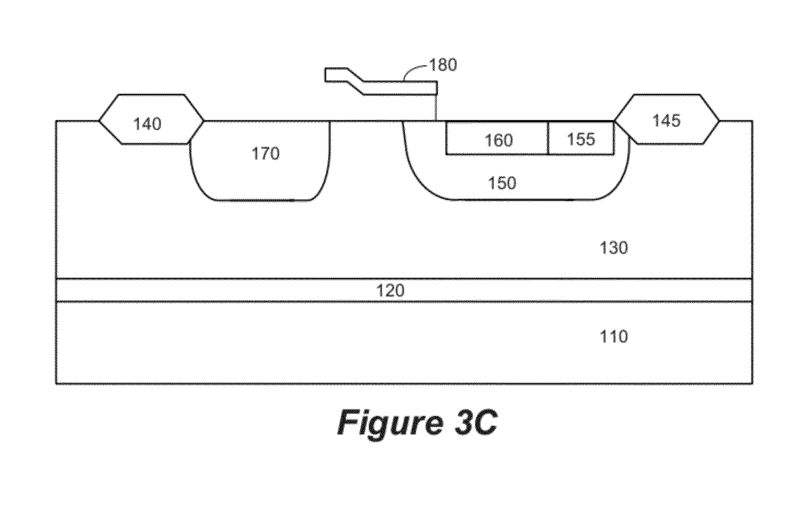

FIGS. 4A and 4B show the corresponding steps within a manufacturing process for a device as shown in FIG. 2. Again, an epitaxial layer 210 is grown on a substrate 215. A insulated gate 250 is then formed above the epitaxial layer 210A mask 450 and the gate 250 define windows 440 and 445 for implanting the P-base regions within which the source regions will be formed. Again, an angled implant beam 410 as described above is used to form the respective regions. Due to the symmetrical nature of the device as shown in FIG. 2, using the same configuration as shown in FIG. 3A would only form an appropriate P-base region under the gate 250 in window 445. A P-base region formed through window 440 would be even less under the gate as with a conventional method. Hence, according to an embodiment, the wafer is rotated as shown with arrow 420 around an axis 430 of the wafer. Thus, respective implants under all edges of an opening are formed. The same technique can also be applied within the method as shown in FIGS. 3A-C as multiple transistors within a chip and wafer may not be all aligned but could be arranged with the device, for example at orthogonal angles. Instead of rotating the wafer, in other embodiments, the beam source can be rotated. FIG. 4B show the respective P-base regions 220 which extend sufficiently under gate 250 while the thermal budget within the manufacturing process has not been exceeded. FIG. 4B also shows the device after the source region 230 and P-base contact region 240 have been formed and drain metal layer 205 has been deposited on the back side.

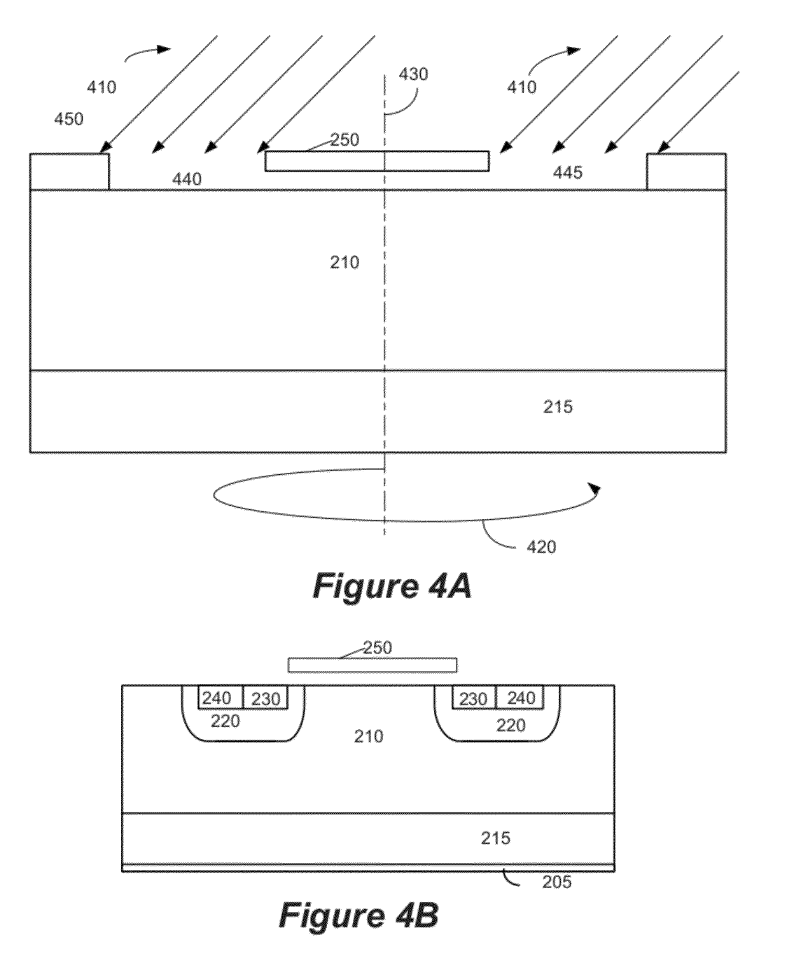

FIG. 5 shows a cross section through a lateral power transistor formed according to an embodiment. As can be seen the P-base region 150 reaches far enough under gate 80 to be able to form a channel. FIG. 5 also shows insulation layer 560 covering the entire device wherein openings are formed to allow contact vias 510 and 520 to contact the source metal runner 530 and contact via 540 to connect the drain region 170 with a respective drain metal runner 550.

All embodiments shown in FIGS. 1-5 show a single cell of respective MOSFETs. The drain and source regions may have a stripe structure. According to other embodiments the cells can however have a square form, a hexagonal shape or any other suitable cell shape for which the principle of the various embodiments can be applied to. The cell structure or a plurality of cells can be used to form a power DMOS-FET within an integrated circuit or in a discrete transistor device. As mentioned above, a module having multiple power transistors may be combined with a driver, a modulation device or a microcontroller. Such modules can be integrated within the existing process flow of such devices without changing the thermal budget. Thus, no additional thermal steps are needed and no changes in the baseline devices will occur. Such an integrated circuit may provide control circuits for example for use in a switched mode power supply that integrates a modulator and/or microcontroller with the power transistors. Thus, no external power transistors may be necessary in respective applications.

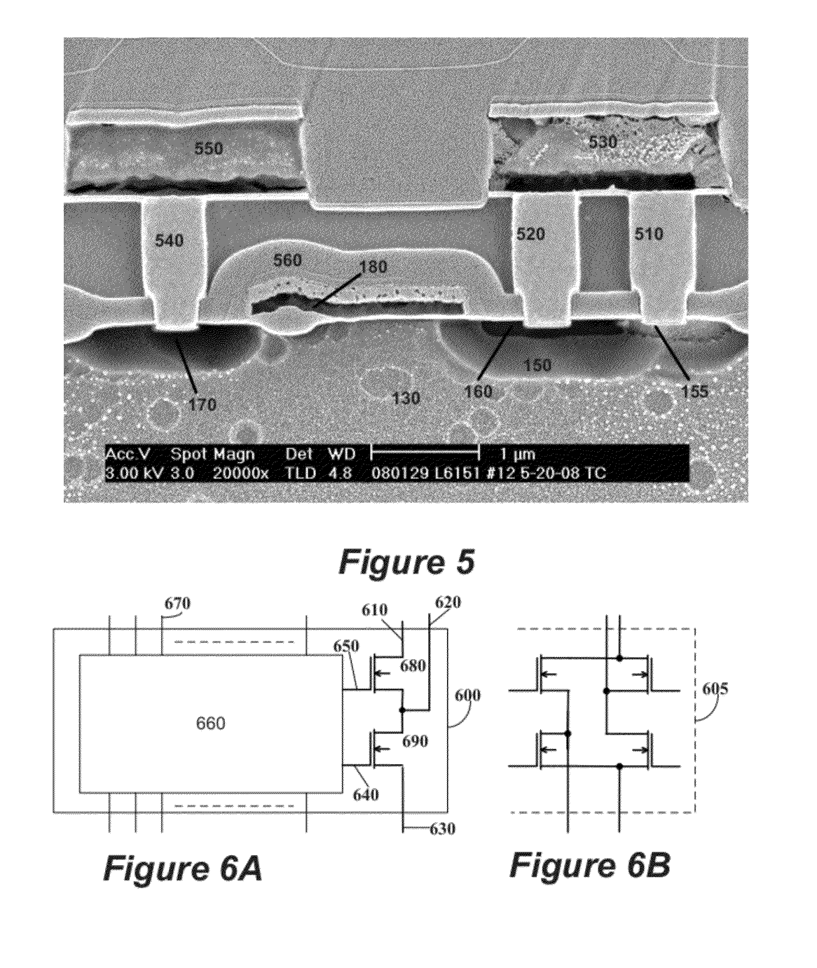

FIG. 6A shows schematically how a microcontroller 660 can be combined with two power transistors 680 and 690 on a single chip 600. Microcontroller 660 may have a plurality of peripheral devices such as controllable drivers, modulators, in particular pulse width modulators, timers etc. and is capable to drive the gates 640 and 650 of transistors 680 and 690 directly or through respective additional drivers. The chip 600 can be configured to make a plurality of functions of the microcontroller available through external connections or pins 670. The source of first transistor 680 can be connected to external connection or pin 610. Similarly, external connection 620 provides a connection to the combined drain and source of transistors 680 and 690 and external connection or pin 630 for the drain of the second transistor 630. Other transistor structures manufactured in accordance with the various embodiments disclosed can be used, such as an H-bridge or multiple single transistors. FIG. 6B shows an exemplary plurality of MOSFETs connected to form an H-Bridge that can be coupled with a microcontroller or modulator within a single semiconductor chip 605.

Furthermore, the exemplary embodiment shows a P-channel device with appropriate dopings of the different regions. A person skilled in the art will appreciate that the embodiments of the present application are not restricted to P-channel devices but can be also applied to N-Channel devices.

What is claimed is:

1. A method for manufacturing a Metal-Oxide-Semiconductor Field-Effect-Transistor (MOSFET) comprising the step of implanting a base region of said MOSFET within an epitaxial layer of a semiconductor chip comprising an insulated gate structure used as a masking element, wherein the implant beam is angled with respect to a vertical axis of the semiconductor chip such that the base region extends sufficiently under the gate to form a Power-MOSFET.

2. The method according to claim 1, wherein the implant beam is angled with respect to a vertical axis of the semiconductor chip with an angle greater than 10 degrees and less than 50 degrees.

3. The method according to claim 1, wherein the MOSFET is formed within a single manufacturing process for forming a plurality of integrated devices and said MOSFET in the semiconductor chip.

4. The method according to claim 3, wherein the plurality of devices form a microcontroller controlling said MOSFET.

5. The method according to claim 3, wherein the plurality of devices form a pulse width modulator controlling said MOSFET.

6. The method according to claim 3, wherein at least two MOSFETs are formed during said manufacturing process and a drain of a first MOSFET is connected to a source of a second MOSFET.

7. The method according to claim 3, wherein a plurality of MOSFETs are formed during said manufacturing process and said plurality of MOSFETs are interconnected to form an H-bridge.

8. The method according to claim 1, wherein the semiconductor chip is rotated around the vertical axis during the step of implanting.

9. The method according to claim 1, wherein the angled implant source is rotated during the step of implanting.

10. The method according to claim 1, wherein the base region is formed on one side of the gate and further comprising forming a source region within the base region implanted by the implanting step.

11. The method according to claim 10, wherein the base MOSFET is formed within an area defined by surrounding field oxide.

12. The method according to claim 11, further comprising the step of forming a buried layer prior to the implanting step.

13. The method according to claim 12, wherein the substrate is an N+ substrate.

14. The method according to claim 12, wherein the substrate is a P-type substrate and the buried layer is an N+ buried layer.

15. The method according to claim 14, wherein the epitaxial layer is a low doped P-type silicon layer comprising selective N-doped regions.

16. The method according to claim 10, further comprising forming a drain region on the other side of the gate extending from a top surface into the epitaxial layer.

17. The method according to claim 16, further comprising forming a plurality of transistor cells within said epitaxial layer and forming metal layers to interconnect said gates, drain and source regions of said plurality of transistor cells.

18. The method according to claim 1, wherein right and left base regions are formed with respect to the gate by rotating the semiconductor chip around the vertical axis during the step of implanting and further comprising the step of forming right and left source regions within the right and left base regions, respectively.

19. The method according to claim 18, further comprising forming a drain region on a backside of said semiconductor chip.

20. The method according to claim 19, further comprising forming a lightly doped drain zone between said left and right base regions.

21. The method according to claim 19, further comprising forming a plurality of transistor cells within said epitaxial layer and forming metal layers to interconnect said gates and source regions of said plurality of transistor cells.
